(19) United States
(12) Patent Application Publication
(10) Pub. No.: US 2026/0182018 A1
(43) Pub. Date: Jun. 25, 2026

(54) COMPLEMENTARY METAL-OXIDE-SEMICONDUCTOR FIELD EFFECT DEVICE

(71) Applicant: IMEC VZW, Leuven (BE)

(72) Inventors: Geert Hellings, Halle (BE); Geert Eneman, Heverlee (BE)

(21) Appl. No.: 19/425,923

(22) Filed: Dec. 18, 2025

(30) Foreign Application Priority Data
Dec. 19, 2024 (EP) 24221652.1

(51) Int. Cl. H10D 84/85; H10D 30/43; H10D 30/62; H10D 62/10; H10D 62/13; H10D 62/822

(52) U.S. Cl. CPC H10D 84/853; H10D 30/43; H10D 30/6211; H10D 62/102; H10D 62/151; H10D 62/822; H10D 84/856

(57) ABSTRACT

The disclosed technology relates to a complementary metal-oxide-semiconductor (CMOS) field effect device comprising a substrate; a first n-doped S/D region and a second n-doped S/D region; a first p-doped S/D region and a second p-doped S/D region; a first channel layer arranged above the substrate, the first channel layer comprising: a first sub-layer and a second sub-layer; wherein the first and second n-doped S/D regions are arranged at a first lateral side of the first channel layer, and the first and second p-doped S/D regions are arranged at a second lateral side of the first channel layer, the second lateral side being opposite to the first lateral side; wherein a conduction band edge of the first sub-layer has an energy below a conduction band edge of the second sub-layer; and wherein a valence band edge of the first sub-layer has an energy below a valence band edge of the second sub-layer; and a gate structure formed over one or more surfaces of the first and second sub-layers of the first channel layer.

### CROSS-REFERENCE TO RELATED APPLICATIONS

This application claims foreign priority to European Patent Application No. EP 24221652.1, filed Dec. 19, 2024, the entire content of which is incorporated by reference herein in its entirety.

### BACKGROUND

### Field

The disclosed technology relates to a complementary metal-oxide-semiconductor (CMOS) field effect device.

### Description of the Related Technology

A CMOS field effect device may utilize both p-type and n-type Metal-Oxide-Semiconductor Field-Effect Transistors (MOSFETs) to create logic functions. A shared-channel CMOS device is an implementation of a CMOS device in which a p-type MOSFET and an n-type MOSFET share a same channel and a same gate. In such a CMOS device, the same channel will conduct electrons when the n-type MOSFET is activated and will conduct holes when the p-type MOSFET is activated.

### SUMMARY OF CERTAIN INVENTIVE ASPECTS

It is an objective of the present disclosure to provide a CMOS device having improved electrical performance. A further objective is to provide a CMOS device having a small footprint. Further and alternative objectives will become more fully apparent from the following description and appended claims.

According to a first aspect, there is provided a CMOS device, the CMOS device comprising:
a substrate;
a first n-doped source/drain (S/D) region and a second n-doped S/D region arranged above the substrate;
a first p-doped S/D region and a second p-doped S/D region arranged above the substrate;
a first channel layer arranged above the substrate, the first channel layer comprising:
   a first sub-layer and a second sub-layer;
wherein the first and second n-doped S/D regions are arranged at a first lateral side of the first channel layer, and the first and second p-doped S/D regions are arranged at a second lateral side of the first channel layer, the second lateral side being opposite to the first lateral side;
wherein the first and second n-doped S/D regions abut the first sub-layer but not the second sub-layer;
wherein the first and second p-doped S/D regions abut the second sub-layer but not the first sub-layer;
wherein a conduction band edge of the first sub-layer has an energy below a conduction band edge of the second sub-layer; and
wherein a valence band edge of the first sub-layer has an energy below a valence band edge of the second sub-layer; and
a gate structure formed over one or more surfaces of the first and second sub-layers of the first channel layer.

The substrate may be a silicon substrate. As used herein, references to an element, e.g. the first channel, being arranged above the substrate can refer to arrangements in which one or more intermediate layers or structures are disposed between the substrate and the first channel. Hence, the first channel layer may be arranged on and in physical contact with such an intermediate layer. That intermediate layer may be, e.g., a functional gate structure, or a portion thereof, or an intermediate dielectric layer.

The CMOS device may comprise a first channel layer. As will be discussed below, the CMOS device may further comprise one or more additional channel layers. For ease of explanation, the first channel layer and the associated S/D regions and gate structure are discussed first. The first channel layer may comprise a first sub-layer and a second sub-layer. In some embodiments, the first and second sub-layers may be arranged very close to each other, arranged adjacent to each other, separated by a minimal spacing, or abutting each other, e.g., in contact with each other. For example, a major surface of the first sub-layer may be arranged adjacent to or in abutment with a major surface of the second sub-layer. Alternatively, a lateral side of the first sub-layer may be arranged adjacent to or in abutment with a lateral side of the second sub-layer. In certain embodiments, the first sub-layer may be in abutment with the second sub-layer. Thus, the CMOS device may be compact, for example, exhibiting a footprint comparable to that of a shared-channel CMOS device. The first channel layer may be patterned to form a nanosheet, or fins. Likewise, the sub-layers of the first channel layer may be patterned to form nanosheets, or fins. As discussed herein, the gate structure may abut the first and second sub-layers of the first channel layer. For example, the gate structure may wrap around the first channel layer. Accordingly, the gate structure may be a wrap-around-gate, also referred to as a gate-all-around (GAA) structure around the first channel layer. For example, the gate structure may abut the first and second lateral side surface of the first channel layer as well as a top and bottom surface of the first channel layer. The gate structure may be arranged between the first and second n-doped S/D regions and between the first and second p-doped S/D regions. A gate structure as discussed herein may include gate spacers, a gate dielectric, and a gate metal.

Since the first and second n-doped S/D regions abut the first sub-layer, the first sub-layer may conduct electrons between the first and second n-doped S/D regions. Similarly, since the first and second p-doped S/D regions abut the second sub-layer, the second sub-layer may conduct holes between the first and second p-doped S/D regions.

In accordance with the above, the first and second n-doped S/D regions and the first sub-layer of the first channel layer may form part of an n-type MOSFET while the first and second p-doped S/D regions and the second sub-layer of the first channel layer may form part of a p-type MOSFET, wherein the n-type MOSFET and the p-type MOSFET may share a common gate structure.

In a conventional shared channel CMOS device, both the n-type MOSFET and the p-type MOSFET may associated with one single homogeneous channel, and thereby the single homogeneous channel will be used to conduct both electrons and holes. Such a conventional shared channel CMOS device may suffer from a limited on-current and/or excessively high leakage currents. For example, when the n-type MOSFET is gated on and the p-type MOSFET is gated off, there may be a leakage current from one of the n-doped S/D regions to one of the p-doped S/D regions.

In contrast, in some embodiments of the present disclosure, the first channel layer may comprise a first and a second sub-layer, wherein the band alignment is such that the conduction band edge of the first sub-layer may have an energy below a conduction band edge of the second sub-layer; and the valence band edge of the first sub-layer may have an energy below a valence band edge of the second sub-layer. For example, the band alignment of the first and second sub-layers may be staggered. Thus, the band alignment of the first and second sub-layers may confine electrons to the first sub-layer and holes to the second sub-layer. Such a configuration may provide a higher on-current and/or reduced leakage currents while maintaining a compact device structure. Further, the first sub-layer may be optimized (or tailored) for electron conduction and/or the second sub-layer may be optimized (or tailored) to hole conduction. This may further improve the on-current.

The first sub-layer may form part of a n-type MOSFET. The first sub-layer may thus be optimized for electron conduction. For example, the first sub-layer may be formed such that the material thereof has a high electron mobility, e.g. a higher electron mobility than the second sub-layer. The material of the first sub-layer may further be configured such that the conduction band edge energy is relatively low as compared to the conduction band edge energy of the material of the second sub-layer. Such a configuration facilitates confinement of electrons within the first sub-layer.

The second sub-layer may form part of a p-type MOSFET. The second sub-layer may thus be optimized for hole conduction. For example, the second sub-layer may be formed such that the material thereof has a high hole mobility, e.g. a higher hole mobility than the first sub-layer. The material of the second sub-layer may further be configured such that the valence band edge energy is relatively high relative as compared to the valence band edge energy of the material of the first sub-layer. Such a configuration facilitates confinement of holes within the second sub-layer.

The first aspect of the disclosure is based on the insight that prior art shared-channel CMOS device, while having a reduced cell area and a reduced gate capacitance compared to conventional CMOS devices, still suffer from issues related to leakage current. In this context, leakage current may refer to primary charge carriers of a MOSFET having a certain conductivity undesirably traversing to the other MOSFET having an opposite conductivity during forward biasing.

In some embodiments, the CMOS device may include a channel comprising a stack of a first sub-layer and a second sub-layer. By configuring a conduction band edge of the first sub-layer to have an energy below a conduction band edge of the second sub-layer, the first sub-layer may be optimized for electron conduction. Such a configuration facilitates confinement of electrons within the first sub-layer. By configuring a valence band edge of the first sub-layer to have an energy below a valence band edge of the second sub-layer, the second sub-layer may be optimized for hole conduction. Such a configuration facilitates confinement of holes within the second sub-layer. Further, the first and second sub-layers may form an interface therebetween. In some embodiments, the first sub-layer may be in abutment with the second sub-layer. As a result of the above configurations of the conduction and valence band edges, a band alignment may be formed at the interface such that the leakage current is reduced during forward biasing of the CMOS device. As discussed above, this reduction may be achieved by confining, or alternatively described as “trapping” the respective primary charge carriers within their respective sub-layer.

In some embodiments, the configurations of the conduction and valence band edges may indicate that the first and second sub-layers may form a heterostructure, e.g., the first and second sub-layers may be formed of different materials. Accordingly, a greater degree of flexibility may be available with respect to selection of materials for the first and second sub-layers. As such, the materials of the first and second sub-layers may be selected to have a small lattice mismatch, thereby enabling a channel layer with reduced epitaxial growth induced defects, such as dislocations. As a result, improved electrical performance and thus a high-quality CMOS device may be achieved. In some embodiments, the materials of the first and second sub-layers may be selected such that the electron mobility is relatively high in the first sub-layer and hole mobility is relatively high in the second sub-layer, thereby improving the drive current of the n-type MOSFET and the p-type MOSFET.

In contrast, in prior art shared-channel CMOS devices, the shared channel is typically formed of a single material. In such devices, conduction is typically biased toward one type of conductivity in the sense that the material will be optimized for either electron conduction or hole conduction. For instance, the shared channel may be formed of Si. However, Si has a significantly higher electron mobility than hole mobility, hence optimizing electron conduction, which is more beneficial for the n-type MOSFET than the p-type MOSFET. This results in a high drive current for the n-type MOSFET and a low drive current for the p-type MOSFET. The disclosed CMOS device addresses this issue by employing a channel that comprises a first sub-layer formed of a material that selected to provide optimal electron conduction, thereby increasing a drive current of the n-type MOSFET, and a second sub-layer formed of a material selected to provide optimal hole conduction and thereby increasing a drive current for the p-type MOSFET.

The first aspect of the disclosure is also based on the insight that a small footprint may be achieved by arranging the n-doped and p-doped S/D regions at respective lateral sides of the first channel layer. By having a small footprint, a thinner device may be realized. Further, by arranging the n-doped and p-doped S/D regions at respective lateral sides, e.g. opposite lateral sides of the first channel layer, the S/D regions may be spatially separated such that the first and second sub-layers may be arranged close to each other, e.g. abutting each other, without the n-doped and p-doped S/D regions coming into contact with each other.

Relative spatial terms such as “topmost”, “bottom”, “lower”, “vertical”, “stacked on top of”, are used herein to describe relative locations or directions within a frame of reference of the semiconductor substrate. In particular, the terms may be understood in relation to a normal direction to the substrate on/above which the stack of channel layers is formed, or equivalently in relation to a bottom-up/stacking direction of the channel layers. The term “lateral surface” or equivalent is used herein to refer to surfaces of the channel layers and/or sub-layers of the channel layers that extend perpendicular to the substrate.

The term “CMOS device” does not require that the CMOS device comprises a single pair of an n-type MOSFET and a p-type MOSFET. Rather, the CMOS device may comprise a plurality of pairs of n-type and p-type MOSFETs, e.g., two, three, four, five, or more pairs.

The use of “first,” “second,” etc., are mainly to be seen as labels facilitating reading and do not necessarily mean that there needs to be further/all the intervening numbers of portions present. To this end, the CMOS device is not limited to comprising one or two channel layers. In fact, the CMOS device may comprise more than two channel layers, wherein each channel layer comprises a sub-layer optimized for electron conduction and a sub-layer optimized for hole conduction. For instance, the CMOS device may comprise three, four, five, or more channel layers. The channel layers may be separated from each other by means of a dielectric layer.

The second sub-layer may comprise Si₁₋ₓGeₓ, wherein x is greater than zero and equal to or less than 1.

Thereby, the second sub-layer may be formed of a material having a comparably high hole mobility. An improved drive current with regard to the p-type MOSFET may be achieved.

The first sub-layer may comprise Si.

Thereby, the second sub-layer may be formed of a material having a comparably high electron mobility. An improved drive current for the n-type MOSFET may be achieved.

The first sub-layer may be tensile strained. The second sub-layer may be compressively strained.

An energy difference between the conduction band edge of the first sub-layer and the valence band edge of the second sub-layer may be equal to or greater than 400 meV.

Such an energy difference may provide a sufficient energy barrier to prevent band-to-band tunneling. In other words, such an energy difference may prevent an electron in the conduction band of the first sub-layer from tunneling into the valence band of the second sub-layer. Similarly, such an energy difference may prevent a hole in the valence band of the second sub-layer from tunneling into the conduction band of the first sub-layer layer. Thereby, leakage current may be reduced.

An energy difference between the conduction band edge of the second sub-layer and the conduction band edge of the first sub-layer may be greater than 100 meV. An energy difference between the valence band edge of the second sub-layer and the valence band edge of the first sub-layer may be greater than 100 meV.

Such energy differences may be characterized as band offsets in the conduction bands and in the valence bands, respectively. Such energy differences may provide sufficient energy barriers for the electrons and holes. Thereby, leakage current may be reduced.

A plane of the first channel layer may be arranged parallel to the substrate;
wherein the first and second n-doped S/D regions may abut one or more of a top surface of the first sub-layer, a bottom surface of the first sub-layer and a lateral side surface of the first sub-layer, and
wherein the first and second p-doped S/D regions may abut one more of a top surface of the second sub-layer, a bottom surface of the second sub-layer, and a lateral side surface of the second sub-layer.

A main plane of the first channel layer may be arranged parallel to a main plane of the substrate.

The CMOS device may further comprise:
a second channel layer arranged above the first channel layer comprising:
   a first sub-layer and a second sub-layer;
wherein the second sub-layer of the first channel layer is arranged above the first sub-layer of the first channel layer, and the second sub-layer of the second channel is arranged below the first sub-layer of the second channel layer, and wherein the first and second p-doped S/D regions abut the second sub-layers of the first and second channel layers, or
wherein the first sub-layer of the first channel layer is arranged above the second sub-layer of the first channel layer, and the first sub-layer of the second channel is arranged below the second sub-layer of the second channel layer, and wherein the first and second n-doped S/D regions abut the first sub-layers of the first and second channel layers.

Unless otherwise specified, the descriptions herein regarding the first channel layer and its sub-layers, including, for example, band alignment, geometry, dimensions, material, and arrangement are also applicable to the second channel layer and its sub-layers.

The gate structure may further abut the first and second sub-layers of the second channel layer.

The gate structure may form a common gate structure for the first and second channel layers. For instance, both the first and second channel layers may be provided with a wrap-around-gate, e.g., a GAA structure. The gate structure may surround at least a portion of the first and second channel layers. The gate structure may thus control both the first and second channel layers.

The CMOS device may further comprise a third n-doped S/D region and a fourth n-doped S/D regions associated with the second channel, and a third p-doped S/D region and a fourth p-doped S/D regions associated with the second channel.

A plane of the first channel layer may be arranged perpendicular to the substrate.

A main plane of the first channel layer may be arranged perpendicular to a main plane of the substrate.

### BRIEF DESCRIPTION OF THE DRAWINGS

The above, as well as additional objects, features and advantages of the present inventive concept, will be better understood through the following illustrative and non-limiting detailed description, with reference to the appended drawings. In the drawings like reference numerals will be used for like elements unless stated otherwise.

FIGS. 1a-1c schematically illustrate various embodiments of CMOS devices in perspective views.

### DETAILED DESCRIPTION OF CERTAIN ILLUSTRATIVE EMBODIMENTS

In the following, various embodiments of CMOS devices are described. In the FIGURES discussed below, axes X, Y, and Z indicate a first direction, a second direction transverse to the first direction, and a vertical or bottom-up direction, respectively. The X- and Y-direction may, in some examples, be referred to as lateral or horizontal directions in that they are parallel to a main plane of the substrate. The Z-direction is parallel to a normal direction of the frontside of the substrate. In certain embodiments, the current flows primarily in the X-direction. Reference herein to a layer being formed may refer to the layer is being formed using conventional semiconductor fabrication technologies, such as metalorganic chemical vapour deposition (MOCVD), physical vapor deposition (PVD), atomic layer deposition (ALD), thin-film deposition, or the like.

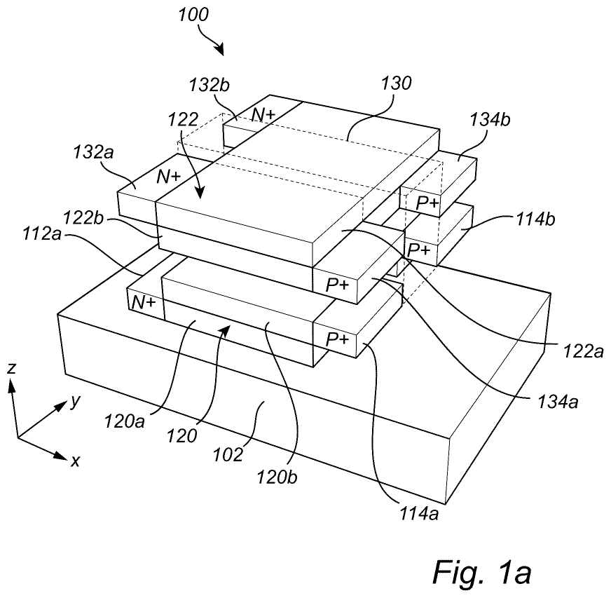

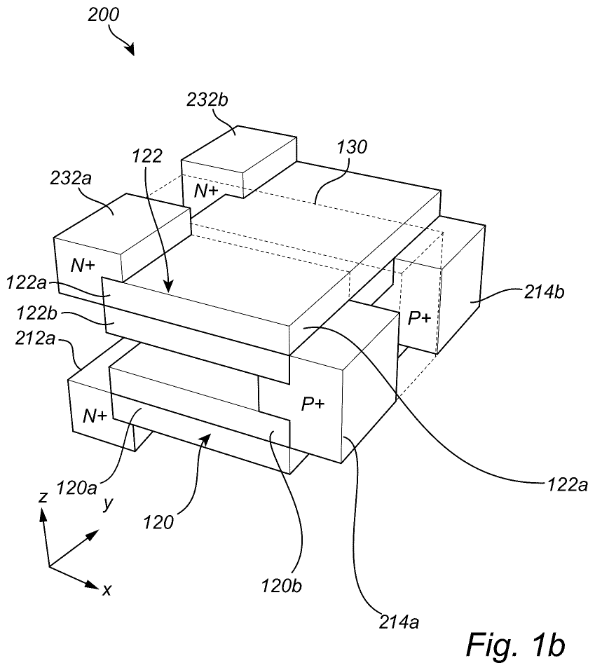

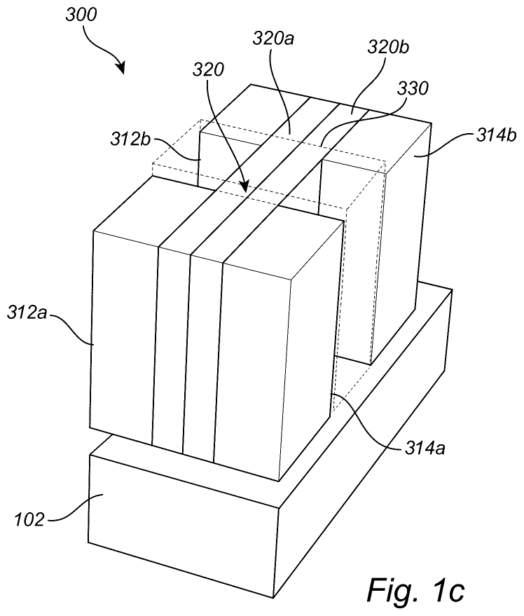

FIG. 1a illustrates a first embodiment of the CMOS device 100. The CMOS device 100 comprises a substrate 102. The substrate 102 may be a conventional semiconductor substrate suitable for, for example, CMOS. The substrate 102 may be, for example, a semiconductor bulk substrate such as a silicon (Si) substrate, a germanium (Ge) substrate or a silicon-germanium (SiGe) substrate. Other suitable examples may include a semiconductor-on-insulator (SOI) type of substrate such as a Si-on-insulator substrate, a Ge-on-insulator substrate, or a SiGe-on-insulator substrate.

The CMOS device 100 further comprises a first channel layer 120. The first channel layer 120 may be in abutment with the substrate 102. In some embodiments, as shown in FIG. 1a, the first channel layer 120 may be arranged above the substrate 102 such that there is a gap therebetween. An intermediate layer may be disposed within the gap. The intermediate layer may be, for example, part of a wrap-around-gate structure, or a dielectric layer.

The first channel layer 120 may comprise a first sub-layer 120a and a second sub-layer 120b. The first sub-layer 120a may form part of an n-type MOSFET. The second sub-layer 120b may form part of a p-type MOSFET.

The first channel layer 120 may be patterned such that it forms a nanosheet. Likewise, the sub-layers of the first channel layer 120 may be patterned to form nanosheets.

The CMOS device 100 may comprise a first n-doped S/D region 112a and a second (not shown) n-doped S/D region 112b. The first n-doped S/D region 112a and the second n-doped S/D region 112b may be arranged above the substrate 102. The first and second n-doped regions 112a, 112b may be arranged at a first lateral side of the first channel layer 120. In some embodiments, the first and second n-doped regions 112a, 112b may be arranged at a lateral side of the first sub-layer 120a. Accordingly, the first and second n-doped regions 112a, 112b are associated with the first sub-layer 120a. In certain embodiments, the first and second n-doped S/D regions 112a, 112b may abut the first sub-layer 120a but not the second sub-layer 120b. The first and second n-doped S/D regions 112a, 112b may abut a lateral side of the first sub-layer 120a. Together, the first and second n-doped regions 112a, 112b and the first sub-layer 120a form part of the n-type MOSFET.

Similarly, the CMOS device 100 may comprise a first p-doped S/D region 114a and a second p-doped S/D region 114b. The first p-doped S/D region 114a and the second p-doped S/D region 114b may be arranged above the substrate 102. The first and second p-doped regions 114a, 114b may be arranged at a second lateral side of the first channel layer 120. In some embodiments, the first and second p-doped regions 114a, 114b may be arranged at a lateral side of the second sub-layer 120b. Accordingly, the first and second p-doped regions 114a, 114b are associated with the second sub-layer 120b. In certain embodiments, the first and second p-doped S/D regions 114a, 114b may abut the second sub-layer 120b but not the first sub-layer 120a. The first and second p-doped S/D regions 114a, 114b may abut a lateral side of the second sub-layer 120b. Together, the first and second p-doped regions 114a, 114b and the second sub-layer 120b form part of the p-type MOSFET.

The second lateral side is arranged opposite to the first lateral side. Accordingly, the first n-doped S/D regions 112a, 112b may be arranged opposite to the first p-doped S/D regions 114a, 114b.

The S/D regions 112a, 112b, 114a, 114b may be formed using methods known in the art. Formation of the S/D regions 112a, 112b, 114a, 114b may comprise metal contact deposition. In some embodiments, the S/D regions 112a, 112b, 114a, 114b may comprise a metal suitable for forming a contact for a S/D region.

The second sub-layer 120b may comprise Si₁₋ₓGeₓ. In this context, x may be equal to or less than 1. For instance, x may be 1, 0.9, 0.8, 0.7, 0.6, 0.5, 0.4, 0.3, 0.2, 0.1, or a value in a range defined by any of these values. The first sub-layer 120a may comprise Si.

The first and second sub-layers 120a, 120b may be subject to strain. For instance, the first sub-layer 120a may be tensilely strained. The second sub-layer 120b may be compressively strained.

A conduction band edge of the first sub-layer 120a may have an energy below a conduction band edge of the second sub-layer 120b. Further, a valence band edge of the first sub-layer 120a may have an energy below a valence band edge of the second sub-layer 120b. Accordingly, the first channel layer 120 may be formed of a heterostructure. In other words, the first sub-layer 120a may be formed of a material being different from that of the second sub-layer 120b. The materials of the sub-layers 120a, 120b may be selected to reduce leakage current, and to optimize electron and/or hole conduction.

The term “band offset” as used herein refers to a relative alignment of energy bands at a semiconductor heterojunction. Accordingly, the energy difference between the conduction band edge of the first sub-layer 120a and the conduction band edge of the second sub-layer 120b may be expressed as a band offset. In some embodiments, an energy difference, e.g., the band offset, between the conduction band edge of the second sub-layer 120b and the conduction band edge of the first sub-layer 120a may be greater than 100 meV. For example, the energy difference between the conduction band edge of the second sub-layer 120b and the conduction band edge of the first sub-layer 120a may be greater than 100 meV, 150 meV, 200 meV, 250 meV, 300 meV, 350 meV, 400 meV, 450 meV, 500 meV, or a value in a range defined by any of these values or higher. Similarly, an energy difference between the valence band edge of the second sub-layer 120b and the valence band edge of the first sub-layer 120a may be greater than 100 meV. For example, the energy difference between the valence band edge of the second sub-layer 120b and the valence band edge of the first sub-layer 120a may be greater than 100 meV, 150 meV, 200 meV, 250 meV, 300 meV, 350 meV, 400 meV, 450 meV, 500 meV, 550 meV, 600 meV, 650 meV, 700 meV, 800 meV, or a value in a range defined by any of these values or higher. As discussed above, these configurations may reduce the leakage current during forward biasing of the CMOS device 100. Further, an energy difference between the conduction band edge of the first sub-layer 120a and the valence band edge of the second sub-layer 120b may be equal to or greater than 400 meV. For example, the energy difference between the conduction band edge of the first sub-layer 120a and the valence band edge of the second sub-layer 120b may be greater than 100 meV, 200 meV, 300 meV, 400 meV, 500 meV, 600 meV, 700 meV, 800 meV, 900 meV, 1 eV, or a value in a range defined by any of these values or higher. This configuration may further reduce the leakage current. Such configurations may be achieved, for example, by the first sub-layer 120a being formed of Si and the second sub-layer being formed of Ge. In other embodiments, the second sub-layer may be formed of Si_{0.5}Ge_{0.5} or Si_{0.75}Ge_{0.25}. In some embodiments, the first and second sub-layers 120a, 120b may be formed as nanosheets to provide the above band offsets. Other layer geometries may also be used.

Still with reference to FIG. 1a, a plane of the first channel layer 120 is arranged parallel to the substrate 102. The first and second n-doped S/D regions 112a, 112b may abut a lateral side surface of the first sub-layer 120a. As noted above, the first channel layer 120 may not be in abutment with the underlying substrate 102. In other embodiments, the first and second n-doped S/D regions 112a, 112b may further abut a bottom surface of the first sub-layer 120a. Similarly, the first and second p-doped S/D regions 114a, 114b may abut a lateral side surface of the second sub-layer 120b. In other embodiments, the first and second p-doped S/D regions 114a, 114b may further abut a top surface of the second sub-layer 120b.

The first and second sub-layers 120a, 120b may not completely overlap. In some embodiments, the second sub-layer 120b may further extended in the y-direction or the x-direction, such that the second sub-layer 120b protrudes beyond the first sub-layer 120a in the respective direction. In other embodiments, the second sub-layer 120b may be disposed inwardly from the perimeter of the first sub-layer 120a. Accordingly, the first and second sub-layers 120a, 120b may partially overlap. The sub-layers 120a, 120b may be dimensioned in various ways such that partial overlap is achieved. In some embodiments, the first and second n-doped S/D regions 112a, 112b may simultaneously abut a top surface of the first sub-layer 120a, a bottom surface of the first sub-layer 120a, and a lateral side surface of the first sub-layer 120a. Similarly, the first and second p-doped S/D regions 114a, 114b may simultaneously abut a top surface of the second sub-layer 120b, a bottom surface of the second sub-layer 120b, and a lateral side surface of the second sub-layer 120b.

Other sequential arrangements of any of the layers or elements of the CMOS device 100 may be employed. For example, while the first sub-layer 120a is depicted as being a bottom layer with respect to the substrate 102, it is contemplated that the second sub-layer 120b may instead be the bottom layer, and the first sub-layer 120a may be the top layer.

Still with reference to FIG. 1a, a second channel layer 122 may be arranged above the first channel layer 120. The second channel layer 122 may comprise a first sub-layer 122a and a second sub-layer 122b. A gap may be arranged between the first channel 120 and the second channel 122. An intermediate layer may be disposed within the gap. The intermediate layer may be, for example, part of a wrap-around-gate structure, or a dielectric layer. Unless otherwise specified, the descriptions herein regarding the first channel layer 120 and its sub-layers 120a, 120b, including, for example, band alignment, geometry, dimensions, material, and arrangement are also applicable to the second channel layer 122 and its sub-layers 122a, 122b.

The relative arrangements of the sub-layers of the first channel layer 120 and the second channel layer 122 are further described below. The second sub-layer 120b of the first channel layer 120 may be arranged above the first sub-layer 120a of the first channel layer 120. Further, the second sub-layer 122b of the second channel 122 may be arranged below the first sub-layer 122a of the second channel 122 layer. As illustrated in FIG. 1a, the second sub-layer 120b of the first channel layer 120 may directly face the second sub-layer 122b of the second channel 122. Other sequential arrangements of any of the layers or elements of the CMOS device 100 may also be employed. For example, the first sub-layer 120a of the first channel layer 120 may be arranged above the second sub-layer 120b of the first channel layer 120. The first sub-layer 122a of the second channel 122 may be arranged below the second sub-layer 122b of the second channel 122 layer. In such embodiment, the first sub-layer 120a of the first channel layer 120 may directly face the first sub-layer 122a of the second channel 122.

A gate structure 130 may abut the second channel 122, and more specifically may abut both the first and second sub-layers 122a, 122b. In some embodiments, the gate structure 130 may abut a top major surface, and lateral side surfaces of the first sub-layer 122a of the second channel 122. In other embodiments, the gate structure 130 may abut a bottom major surface, and lateral side surfaces of the second sub-layer 122b of the second channel 122. The gate structure 130 may also abut the first channel 120, and more specifically the first and second sub-layers 120a, 120b. For instance, the gate structure 130 may abut a top major surface, and lateral side surfaces of the second sub-layer 120b of the first channel 120. Likewise, the gate structure 130 may abut a bottom major surface and lateral side surfaces of the first sub-layer 120a of the first channel 120. In some embodiments, the gate structure 130 may form a wrap-around-gate, e.g., GAA structure. In such embodiments, the gate structure 130 may surround the first and second channel layers 120, 122. In other words, the gate structure 130 may abut a bottom surface of the first channel layer 120, a top surface of the second channel layer 122, and at least one lateral surface of each of the first and second channel layers 120, 122. Hence, the gate structure 130 may control both the first and second channel layers 120, 122. In other embodiments, the gate structure 130 may extend between the first and second channel layers 120, 122.

The CMOS device 100 may further comprise a third n-doped S/D region 132a and a fourth n-doped S/D region 132b associated with the second channel 122. Thus, the third and fourth n-doped S/D regions 132a, 132b may form part of a second n-type MOSFET. The CMOS device 100 may further comprise a third p-doped S/D region 134a and a fourth p-doped S/D region 134b associated with the second channel 122. Thus, the third and fourth p-doped S/D regions 134a, 134b may form part of a second p-type MOSFET. Unless otherwise specified, the descriptions herein regarding the first and second n-doped S/D regions 112a, 112b and/or the first and second p-doped S/D regions 114a, 114b, including, for example, geometry, dimensions, material, and arrangement are also applicable to the third and fourth n-doped S/D regions 132a, 132b and/or the third and fourth p-doped S/D regions 134a, 134b.

Along a bottom-up direction, the layers and/or elements of the CMOS device 100 may be arranged, for example, in the following order: substrate 102; first sub-layer 120a and first and second n-doped source/drain regions 112a, 112b of the first channel 120; second sub-layer 120b and first and second p-doped source/drain regions 114a, 114b of the first channel 120; second sub-layer 122b and first and second p-doped source/drain regions 134a, 134b of the second channel 122; first sub-layer 122a and first and second n-doped source/drain regions 132a, 132b of the second channel 122.

However, as noted above, other sequential arrangements of any of the layers and/or elements of the CMOS device 100 may be employed. For instance, along a bottom-up direction, the layers/elements of the CMOS device 100 may alternatively be arranged in the following order: substrate 102; second sub-layer 120b and first and second p-doped source/drain regions 114a, 114b of the first channel 120; first sub-layer 120a and first and second n-doped source/drain regions 112a, 112b of the first channel 120; first sub-layer 122a and first and second n-doped source/drain regions 132a, 132b of the second channel 122; second sub-layer 122b and first and second p-doped source/drain regions 134a, 134b of the second channel 122.

FIG. 1b illustrates a second embodiment of the CMOS device 200, For illustrative purposes, the substrate is not shown. The CMOS device 200 is similar to the first CMOS device 100 as illustrated in FIG. 1a. Therefore, for sake of brevity, a detailed discussion about the CMOS device 200 has been omitted. Unless otherwise stated, the above discussions regarding corresponding layer and/or element of the first embodiment of the CMOS device 100 including geometry, dimensions, material, and arrangement, are also applicable to the layer and/or element in the second CMOS device 200. A main difference between the second embodiment of the CMOS device 200 and the first embodiment of the CMOS device 100 is the presence of first and second p-doped S/D regions 214a, 214b associated with both the first channel layer 120 and the second channel layer 122. Hence, a single unit of each respective first and second p-doped S/D region 214a, 214b may abut and be associated with both the first and second channel layers 120, 122. In contrast, the first embodiment of the CMOS device 100 may comprise separate first and second p-doped S/D regions 114a, 114b associated with the first channel layer 120, and separate third and fourth p-doped S/D regions 134a, 134b associated with the second channel 122. In the second embodiment of the CMOS device 200 shown in FIG. 1b, the first and second p-doped S/D regions 214a, 214b may extend between the first and second channel layers 120, 122. In certain embodiments, the first and second p-doped S/D regions 214a, 214b may abut the second sub-layers 120b, 122b of the first and second channel layers 120, 122.

Another main difference between the second embodiment of the CMOS device 200 and the first embodiment of the CMOS device 100 is that, in the second embodiment, the first and second n-doped S/D regions 212a, 212b associated with the first channel layer 120 may further abut a bottom surface of the first channel layer 120, e.g., a bottom surface of the first sub-layer 120a. Similarly, in the second embodiment, the third and fourth n-doped S/D regions 232a, 232b associated with the second channel layer 122 may abut a top surface of the second channel layer 122, e.g., a top surface of the first sub-layer 122a. Further, the sequential arrangement of the layers and/or elements may vary from what is shown in FIG. 1b. For example, the first sub-layers 120a, 122a may directly face each other. Accordingly, the first and second n-doped S/D regions 212a, 212b may alternatively form a single unit and may further abut the first sub-layers 120a, 122a of the first and second channel layers 120, 122 respectively. In such configuration, there would be provided separate p-doped S/D regions associated with the first channel layer 120, and separate p-doped S/D regions associated with the second channel layer 122.

FIG. 1c illustrates a third embodiment of the CMOS device 300. The third embodiment of the CMOS device 300 may comprise a substrate 102 and a first channel layer 320 comprising first and second sub-layers 320a, 320b. The third embodiment of the CMOS device 300 may further comprise first and second n-doped S/D regions 312a, 312b associated with the first sub-layer 320a, such that the first sub-layer 320a forms part of an n-type MOSFET. The third embodiment of the CMOS device 300 may further comprise first and second p-doped S/D regions 314a, 314b associated with the second sub-layer 320b, such that the second sub-layer 320b forms part of a p-type MOSFET. A main difference between the third embodiment of the CMOS device 300 and the first and second embodiments of the CMOS devices 100, 200 is that a plane, e.g., a main plane, of the first channel layer 320 may be arranged perpendicular to the substrate 102. Accordingly, the first channel layer 320 and its sub-layers 320a, 320b may be formed as fins, instead of, e.g., nanosheets, with a major extension in the z-direction. The first and second n-doped S/D regions 312a, 312b may be arranged at a first lateral side of the channel layer 320, for example, abutting a lateral side of the first sub-layer 320a. The first and second p-doped S/D regions 314a, 314b may be arranged at a second lateral side of the channel layer 320, for example, abutting a lateral side of the first sub-layer 320b. The first lateral side is arranged opposite to the second lateral side.

A gate structure 330 may, as illustrated, straddle the channel layer 320. The illustrated gate structure 330 may abut the first and second sub-layers 320a, 320b of the first channel layer 320. The first channel layer 320 may be arranged above the substrate 102 such that a gate portion is disposed therebetween. In other embodiments, the gate structure 330 may be formed as a GAA structure that extends between the substrate 102 and the first channel layer 320.

The above discussions concerning e.g. formation methods and material choices of the substrate, the S/D regions, and the channel layers are also applicable to the corresponding layers/elements of the CMOS device 300.

In any of the first, second, and third embodiments of the CMOS device 100, 200, and 300, the first and second sub-layers of the first channel layer may be spaced apart by a distance of about 1 to about 10 nm, e.g., 1, 2, 3, 4, 5, 6, 7, 8, 9, or 10 nm, or a value in a range defined by any of these values. This may also be applicable to any second channel layers. The first and second sub-layers of the second channel layer may be arranged within a distance of about 1 to about 10 nm, e.g., 1, 2, 3, 4, 5, 6, 7, 8, 9, or 10 nm, or a value in a range defined by any of these values.

In the above the inventive concept has mainly been described with reference to a limited number of examples. However, as is readily appreciated by a person skilled in the art, other examples than the ones disclosed above are equally possible within the scope of the inventive concept, as defined by the appended claims.

What is claimed is:

1. A complementary metal-oxide-semiconductor (CMOS) field effect device comprising:
a substrate;
a first n-doped source/drain (S/D) region and a second n-doped S/D region arranged above the substrate;
a first p-doped S/D region and a second p-doped S/D region arranged above the substrate;
a first channel layer arranged above the substrate, the first channel layer comprising:
a first sub-layer and a second sub-layer;
wherein the first and second n-doped S/D regions are arranged at a first lateral side of the first channel layer, and the first and second p-doped S/D regions are arranged at a second lateral side of the first channel layer, the second lateral side being opposite to the first lateral side;
wherein the first and second n-doped S/D regions abut the first sub-layer and not abut the second sub-layer;
wherein the first and second p-doped S/D regions abut the second sub-layer and not abut the first sub-layer;
wherein a conduction band edge of the first sub-layer has an energy below a conduction band edge of the second sub-layer; and
wherein a valence band edge of the first sub-layer has an energy below a valence band edge of the second sub-layer; and
a gate structure formed over one or more surfaces of the first and second sub-layers of the first channel layer.

2. The CMOS field effect device according to claim 1, wherein the second sub-layer comprises Si₁₋ₓGeₓ, wherein x is greater than zero and equal to or less than 1.

3. The CMOS field effect device according to claim 1, wherein the first sub-layer comprises Si.

4. The CMOS field effect device according to claim 1, wherein the first sub-layer is tensile strained, and wherein the second sub-layer is compressively strained.

5. The CMOS field effect device according to claim 1, wherein an energy difference between the conduction band edge of the first sub-layer and the valence band edge of the second sub-layer is equal to or greater than 400 meV.

6. The CMOS field effect device according to claim 1, wherein an energy difference between the conduction band edge of the second sub-layer and the conduction band edge of the first sub-layer is greater than 100 meV.

7. The CMOS field effect device according to claim 1, wherein an energy difference between the valence band edge of the second sub-layer and the valence band edge of the first sub-layer is greater than 100 meV.

8. The CMOS field effect device according to claim 1, wherein the gate structure abuts the first and second sub-layers of the first channel layer.

9. The CMOS field effect device according to claim 1,
wherein a plane of the first channel layer is arranged parallel to the substrate;
wherein the first and second n-doped S/D regions abut one or more of a top surface of the first sub-layer, a bottom surface of the first sub-layer and a lateral side surface of the first sub-layer, and
wherein the first and second p-doped S/D regions abut one more of a top surface of the second sub-layer, a bottom surface of the second sub-layer, and a lateral side surface of the second sub-layer.

10. The CMOS field effect device according to claim 9, further comprising:
a second channel layer arranged above the first channel layer, wherein the second channel layer comprises a first sub-layer and a second sub-layer.

11. The CMOS field effect device according to claim 10, wherein the second sub-layer of the first channel layer is arranged above the first sub-layer of the first channel layer, and the second sub-layer of the second channel is arranged below the first sub-layer of the second channel layer, and wherein the first and second p-doped S/D regions abut the second sub-layers of the first and second channel layers, respectively.

12. The CMOS field effect device according to claim 10, wherein the first sub-layer of the first channel layer is arranged above the second sub-layer of the first channel layer, and the first sub-layer of the second channel is arranged below the second sub-layer of the second channel layer, and wherein the first and second n-doped S/D regions abut the first sub-layers of the first and second channel layers, respectively.

13. The CMOS field effect device according to claim 10, wherein the gate structure abuts the first and second sub-layers of the second channel layer.

14. The CMOS field effect device according to claim 10, further comprising a third n-doped S/D region and a fourth n-doped S/D region associated with the second channel, and a third p-doped S/D region and a fourth p-doped S/D region associated with the second channel.

15. The CMOS field effect device according to claim 1, wherein a plane of the first channel layer is arranged perpendicular to the substrate.

16. The CMOS field effect device according to claim 8, wherein the gate structure abuts a top and a bottom surface of the first channel layer, and a first lateral side surface and a second lateral side surface of the first channel layer.

17. The CMOS field effect device according to claim 13, wherein the gate structure abuts a bottom surface of the first channel layer, a top surface of the second channel layer, and at least one lateral surface of each of the first and second channel layers.

18. The CMOS field effect device according to claim 1, wherein at least one of the first sub-layer and the second sub-layer of the first channel layer is formed as a nanosheet.

19. The CMOS field effect device according to claim 15, wherein at least one of the first sub-layer and the second sub-layer of the first channel layer is formed as a fin structure extending away from the substrate.
